(19) United States
(12) Patent Application Publication
(10) Pub. No.: US 2009/0166628 A1
(43) Pub. Date: Jul. 2, 2009

(54) IMAGE SENSOR AND METHOD FOR MANUFACTURING THE SAME

(76) Inventor: Chang-Hun Han, Icheon-si (KR)

Correspondence Address: SHERR & VAUGHN, PLLC, 620 HERNDON PARKWAY, SUITE 200, HERNDON, VA, 20170, US

(21) Appl. No.: 12/344,493

(22) Filed: Dec. 27, 2008

(30) Foreign Application Priority Data
Dec. 27, 2007 (KR) 10-2007-0139465

(51) Int. Cl. H01L 31/0376; H01L 31/18

(52) U.S. Cl. 257/53; 438/96; 438/57; 257/E31.047

(57) ABSTRACT

An image sensor includes a first substrate having a circuitry including a wire formed therein and a photodiode formed above the circuitry. An unevenness is formed at the top of the photodiode. The unevenness may, for example, be formed by selectively etching the top of the photodiode and may act to maximize light absorption by the photodiode.

The present application claims priority under 35 U.S.C. 119 to Korean Patent Application No. 10-2007-0139465 (filed on Dec. 27, 2007), which is hereby incorporated by reference in its entirety.

### BACKGROUND

Generally, an image sensor is a semiconductor device that converts an optical image into an electrical signal. Image sensors can generally be classified as either a charge coupled device (CCD) image sensor or a complementary metal oxide silicon (CMOS) image sensor (CIS). The CMOS image sensor obtains an image by forming a photodiode and a MOS transistor in each unit pixel to sequentially detect electrical signals of the respective unit pixels in a switching mode. A related CMOS image sensor may be constructed with a structure in which the photodiode and the transistor are disposed side by side.

Although many disadvantages of the CCD image sensor have been resolved by related horizontal type CMOS image sensors, such CMOS sensors may themselves have disadvantages. For example, in a related horizontal type CMOS image sensor, the photodiode and transistor are disposed side by side, while being adjacent to each other, on a substrate. Consequently, an additional region is utilized for the photodiode, and, as a result, fill factor is reduced and possible resolution is limited.

Also, in related horizontal type CMOS image sensors, light incident on the photodiode is not properly absorbed, but, instead, a large portion of the light may be reflected so that it does not contribute to an image signal. Moreover, in related horizontal type CMOS image sensors, it is difficult to optimize a process for manufacturing the photodiode and the transistor at the same time. That is, a shallow junction may be used for its low sheet resistance when manufacturing the transistor, whereas the shallow junction may not be suitable for manufacturing the photodiode.

Additionally, when additional on-chip functions are added to a related horizontal type CMOS image sensor, either the size of the unit pixel must increase to maintain the sensitivity of the image sensor or the area required for the photodiode must decrease to maintain the pixel size. If the pixel size increases, however, the resolution of the image sensor may decrease and, if the photodiode area decreases, the sensitivity of the sensor may decrease.

### SUMMARY

Embodiments relate to an image sensor that maximizes absorption of light incident on a photodiode and a method for manufacturing the same. Embodiments relate to an image sensor that maximizes both resolution and sensitivity and a method for manufacturing the same. Also, embodiments relate to an image sensor that adopts a vertical type photodiode and minimizes the occurrence of defects in the photodiode and a method for manufacturing the same.

Embodiments relate to an image sensor that may include a first substrate having circuitry including a wire formed therein and a photodiode formed above the circuitry, and an unevenness being formed at the top of the photodiode. Embodiments relate to a method for manufacturing an image sensor that may include forming circuitry including a wire in a substrate, forming a photodiode above the circuitry, and forming an unevenness at a top of the photodiode.

### DRAWINGS

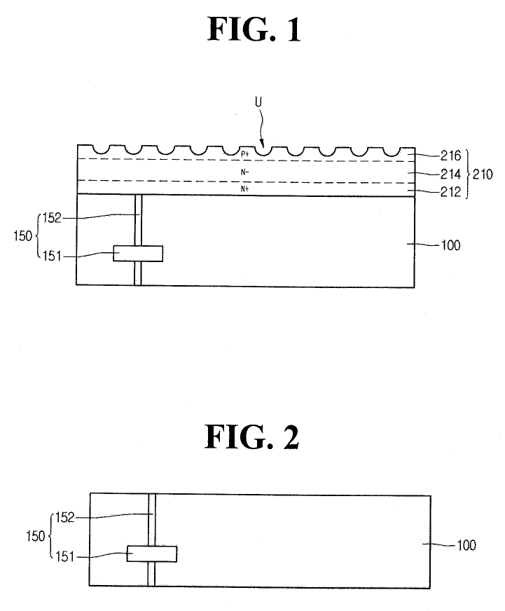

Example FIG. 1 is a sectional view illustrating an image sensor according to embodiments.

Example FIGS. 2 to 8 are process sectional views illustrating a method for manufacturing the image sensor according to embodiments.

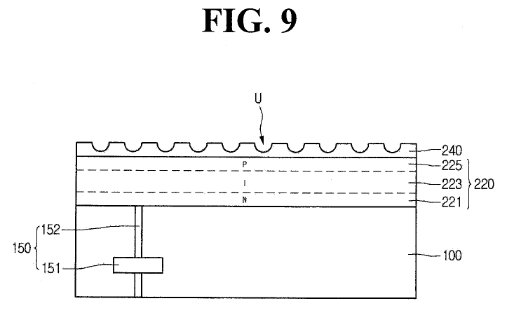

Example FIG. 9 is a sectional view illustrating an image sensor according to embodiments.

### DESCRIPTION

In the description of preferred embodiments of the present invention, when describing any member as formed “on or under” each layer, the description includes the member being directly or indirectly formed on or under each layer. Also, embodiments are not limited to a CMOS image sensor but may be applicable to any image sensor utilizing a photodiode.

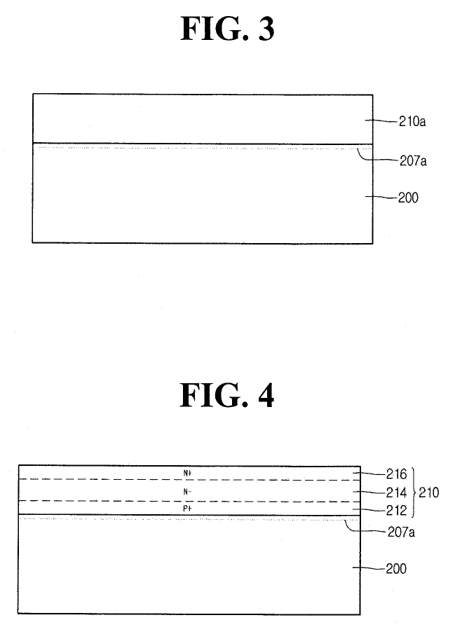

Example FIG. 1 is a sectional view illustrating an image sensor according to embodiments. The image sensor may include a first substrate 100 having circuitry including a wire 150 formed therein, and a photodiode 210 formed above the circuitry. An unevenness U may be formed at the top of the photodiode 210. For example, the photodiode 210 may be formed in a crystalline semiconductor layer 210a (see example FIG. 3).

Accordingly, the photodiode 210 is a vertical type photodiode located above the circuitry, and the photodiode 210 may be formed in the crystalline semiconductor layer 210a, thereby reducing, or even preventing, the occurrence of defects in the photodiode. Also, the unevenness U may be formed at the top of the photodiode 210, thereby maximizing light absorption.

As shown in example FIG. 2, a first substrate 100 having circuitry including a wire 150 formed therein is prepared. For example, a shallow trench isolation may be formed at the first substrate 100 to define an active region, and circuitry including a transistor may be formed at the active region. The wire 150 may, for example, include a metal 151 and a plug 152.

Also, as shown in example FIG. 3, a crystalline semiconductor layer 210a may formed on a second substrate 200. A photodiode may be formed in the crystalline semiconductor layer 210a so as to reduce or prevent the occurrence of defects in the photodiode. For example, the crystalline semiconductor layer 210a may be formed on the second substrate 200 by an epitaxial growth. Subsequently, hydrogen ions may be implanted into the interface between the second substrate 200 and the crystalline semiconductor layer 210a to form a hydrogen ion implantation layer 207a. The implantation of the hydrogen ions may be performed after ion implantation for forming a photodiode 210.

As shown in example FIG. 4, ions may be implanted into the crystalline semiconductor layer 210a to form a photodiode 210. For example, a second conductive layer 216 may be formed in the upper part of the crystalline semiconductor layer 210a. For example, a high-concentration P-type conductive layer 216 may be formed in the upper part of the crystalline semiconductor layer 210a by implanting ions into substantially the whole surface of the second substrate 200 by a blanket without a mask. The second conductive layer 216 may be formed with a junction depth of less than approximately 0.5 μm.

A first conductive layer 214 may be formed at the bottom of the second conductive layer 216. For example, a low-concentration N-type conductive layer 214 may be formed at the bottom of the second conductive layer 216 by implanting ions into substantially the whole surface of the second substrate 200 by a blanket without a mask. The low-concentration first conductive layer 214 may be formed with a junction depth of approximately 1.0 to 2.0 μm.

Subsequently, a step of forming another first conductive layer 212 at the bottom of the first conductive layer 214 may be performed. For example, a high-concentration N-type conductive layer 212 may be formed at the bottom of the first conductive layer 214 by implanting ions into substantially the whole surface of the second substrate 200 by a blanket without a mask, thereby contributing to ohmic contact.

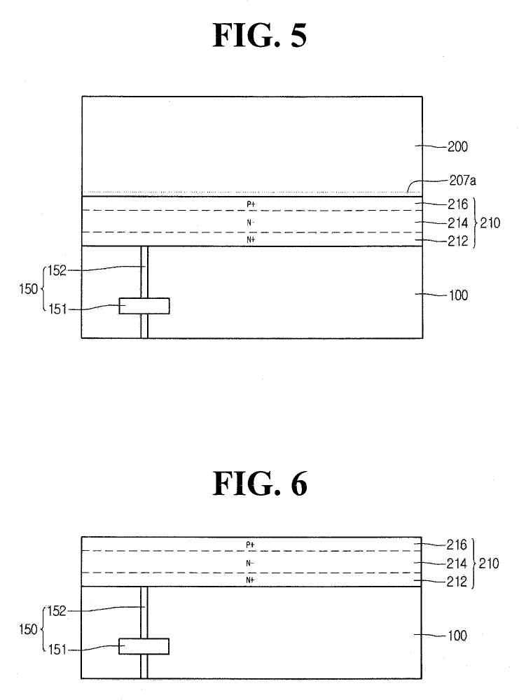

As shown in example FIG. 5, the first substrate 100 and the second substrate 200 may be bonded to each other such that the photodiode 210 is electrically coupled with the wire 150. For example, the surface energy at the surfaces to be bonded may be increased by plasma activation before bonding the first substrate 100 and the second substrate 200, and then the bonding process may be performed. The second substrate 200 may be heat-treated such that the hydrogen ion implantation layer 207a changes into a hydrogen gas layer.

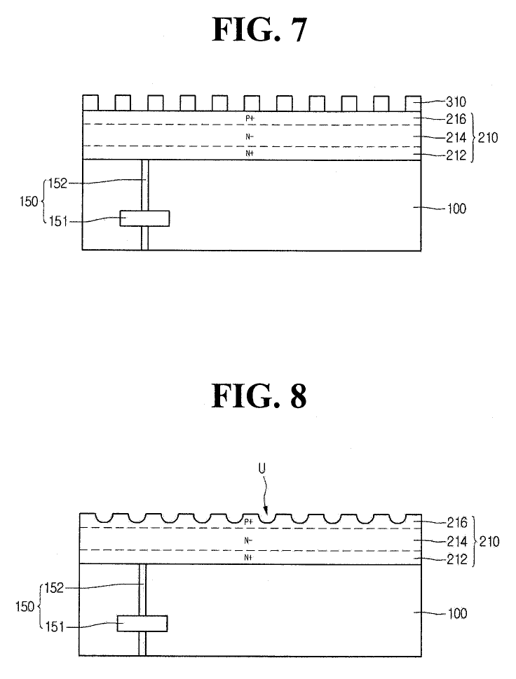

As shown in example FIG. 6, the lower part of the second substrate 200 from the hydrogen gas layer may be removed, for example, by a blade to expose the photodiode 210; and as shown in example FIG. 7, a photosensitive film pattern 310 may be formed on, or over, the exposed photodiode 210. For example, the photosensitive film pattern 310 may be formed on, or over, the photodiode 210 by a photo process such that the photosensitive film pattern 310 selectively exposes the photodiode 210 at predetermined intervals. Alternatively, the photosensitive film pattern 310 may be configured in a texture type lattice structure. In addition, the photosensitive film pattern 310 may be obtained by a scattering process instead of a photo process.

As shown in example FIG. 8, the upper part of the photodiode 210 may be selectively etched, using the photosensitive film pattern 310 as an etch mask, to form an unevenness U, and then the photosensitive film pattern 310 is removed. For example, the second conductive layer 216 of the photodiode 210 may be selectively etched to form the unevenness U.

According to embodiments, an insulation film may be further formed on, or over, the photodiode 210 before forming the photosensitive film pattern 310, the photosensitive film pattern may be formed on the insulation film, and the insulation film and the upper part of the photodiode may be etched. A subsequent etching process may be performed to separate the photodiode 210 into pixel units, and the etched parts may be filled with an inter-pixel insulation layer. Also, a process for forming a top electrode and a color filter may be performed.

Example FIG. 9 is a sectional view illustrating an image sensor according to embodiments. The image sensor may include a first substrate 100 having circuitry including a wire 150 formed therein, and a photodiode 220 formed above the circuitry. An unevenness U may be formed at the top of the photodiode 220. A top electrode 240 may further be formed on the photodiode 220. The unevenness U may be formed at the top of the top electrode 240.

In accordance with example FIG. 9, the photodiode 220 may be formed in an amorphous layer. For example, the photodiode 220 may include an intrinsic layer 223 electrically connected to the wire 150 and a second conductive layer 225 formed on the intrinsic layer 223. Also, a first conductive layer 221 formed between the wire 150 and the intrinsic layer 223 may also be included.

The photodiode 220 may be formed by depositing the photodiode 220 on the first substrate 100 having the circuitry including the wire 150 formed therein, but not necessarily by bonding between the substrates. For example, the first conductive layer 221 may be formed on, or over, the first substrate 100 such that the first conductive layer 221 contacts the wire 150. However, subsequent processes may be performed without forming the first conductive layer 221.

The first conductive layer 221 may serve as an N layer of the PIN diode. That is, the first conductive layer 221 may be, but is not limited to, an N-type conductive layer. The first conductive layer 221 may be formed of, but is not limited to, n-doped amorphous silicon. That is, the first conductive layer 221 may be formed of a-Si:H, a-SiGe:H, a-SiC, a-SiN:H, or a-SiO:H, which are obtained by adding germanium, carbon, nitrogen, or oxygen to the amorphous silicon. Also, the first conductive layer 221 may be formed by chemical vapor deposition (CVD), particularly plasma enhanced CVD (PECVD). For example, the first conductive layer 221 may be formed of amorphous silicon by PECVD using a silane (SiH₄) gas mixed with PH₃ or P₂H₅.

The intrinsic layer 223 may be formed on, or over, the first conductive layer 221. The intrinsic layer 223 may serve as an I layer of the PIN diode. The intrinsic layer 223 may be formed of amorphous silicon. The intrinsic layer 223 may be formed by CVD, particularly PECVD. For example, the intrinsic layer 223 may be formed of amorphous silicon by PECVD using a silane (SiH₄) gas.

A second conductive layer 225 may be formed on, or over, the intrinsic layer 223. The intrinsic layer 223 and the second conductive layer 225 may be successively formed. The second conductive layer 225 may serve as a P layer of the PIN diode. That is, the second conductive layer 225 may be, but is not limited to, a P-type conductive layer. The second conductive layer 225 may be formed of, but is not limited to, p-doped amorphous silicon. For example, the second conductive layer 225 may be formed of amorphous silicon by PECVD using a silane (SiH₄) gas mixed with boron.

The top electrode 240 may be formed on, or over, the second conductive layer 225. For example, the top electrode 240 may be a transparent electrode exhibiting high light transmittance and conductivity. For example, the top electrode 240 may be made of indium tin oxide (ITO) or cadmium tin oxide (CTO). Also, a photosensitive film pattern may be formed on the top electrode 240. For example, the photosensitive film pattern may be formed on the top electrode 240 by a photo process such that the photosensitive film pattern selectively exposes the top electrode 240 at predetermined intervals. Alternatively, the photosensitive film pattern may be configured in a texture type lattice structure. In addition, the photosensitive film pattern may be obtained by a scattering process, not by the photo process.

The upper part of the top electrode 240 may then be selectively etched, using the photosensitive film pattern as an etch mask, to form an unevenness U, and then the photosensitive film pattern may be removed.

According to embodiments an image sensor and the method for manufacturing the same includes vertical integration of the circuitry and the photodiode and may maximize light absorption by forming the unevenness at the top of the photodiode. According to embodiments a fill factor of approximately 100% is achievable through the vertical integration of the circuitry and the photodiode.

According to embodiments, sensitivity is maximized per pixel size, resolution is maximized, and process costs are minimized. Also, complicated circuitry may be utilized without reducing the sensitivity at each unit pixel. According to embodiments, performance of the image sensor may be maximized, while minimizing the size of the device and manufacturing costs, through additional on-chip circuitry integrated therein.

According to embodiments, one or more of the following beneficial effect may occur: vertical integration of the circuitry and the photodiode; maximizing light absorption by forming the unevenness at the top of the photodiode; approximately a 100% fill factor through vertical integration; maximizing sensitivity at the same pixel size through the vertical integration; maximizing resolution while minimizing process costs; and implementing more complicated circuitry without the reduction of sensitivity at each unit pixel. Also, according to embodiments the performance of the image sensor may be maximized, the size of the device may be minimized, and the manufacturing costs may be minimized, through the provision of additional on-chip circuitry integrated therein.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. A method for manufacturing an image sensor, comprising:
forming circuitry including a wire in a substrate;
forming a photodiode above the circuitry;
forming a top electrode over the photodiode; and
treating a top surface of the top electrode so that the top surface is uneven.

2. The method according to claim 1, wherein treating the top surface includes:
selectively etching the top surface using a photosensitive film pattern over the top electrode as an etch mask.

3. The method according to claim 1, wherein forming the photodiode includes:
forming an intrinsic layer electrically coupled with the wire, and
forming a conductive layer over the intrinsic layer.

4. The method according to claim 3, wherein the intrinsic layer comprises amorphous silicon.

5. The method according to claim 4, wherein forming the intrinsic layer includes:
performing chemical vapor deposition.

6. The method according to claim 4, wherein forming the intrinsic layer includes:
performing plasma enhanced chemical vapor deposition.

7. The method according to claim 1, wherein the top electrode comprises indium tin oxide.

8. The method according to claim 1, wherein the top electrode comprises cadmium tin oxide.

9. The method according to claim 1, wherein the uneven top surface includes regularly spaced portions have a height lower than adjacent portions.

10. An image sensor of claim 1, comprising:
a circuitry including a wire in a substrate;
a photodiode above the circuitry and electrically coupled with the wire; and
a top electrode over the photodiode, wherein a top surface of the top electrode is uneven.

11. The image sensor of claim 10, wherein the photodiode includes:
an intrinsic layer electrically coupled with the wire; and
forming a second conductive layer on the intrinsic layer.

12. The image sensor of claim 11, wherein the intrinsic layer is formed of amorphous silicon.

13. The image sensor of claim 11, wherein the intrinsic layer is formed by chemical vapor deposition.

14. The image sensor of claim 11, wherein the intrinsic layer is formed by plasma enhanced chemical vapor deposition.

15. The image sensor of claim 10, wherein the top electrode comprises indium tin oxide.

16. The image sensor of claim 10, wherein the top electrode comprises cadmium tin oxide.

17. The image sensor of claim 10, wherein the uneven top surface includes regularly spaced portions have a height lower than adjacent portions.

18. A method for manufacturing an image sensor, comprising:
forming circuitry including a wire in a substrate;
forming a photodiode above the circuitry; and
treating a top surface of the photodiode so that the top surface is uneven.

19. The method according to claim 18, wherein treating the top surface includes:
selectively etching the top surface using a photosensitive film pattern over the top surface as an etch mask.

20. The method according to claim 18, wherein the uneven top surface includes regularly spaced portions have a height lower than adjacent portions.
